(19) United States
(12) Patent Application Publication
(10) Pub. No.: US 2025/0388461 A1
(43) Pub. Date: Dec. 25, 2025

(54) MOLDED FLUIDIC INTEGRATED CIRCUIT DIES WITH EMBEDDED VIA STRUCTURES

(71) Applicant: Hewlett-Packard Development Company, L.P., Spring, TX (US)

(72) Inventors: Bo Song, Corvallis, OR (US); Chien-Hua Chen, Corvallis, OR (US); Fan Wu, Corvallis, OR (US)

(73) Assignee: Hewlett-Packard Development Company, L.P., Spring, TX (US)

(21) Appl. No.: 18/750,949

(22) Filed: Jun. 21, 2024

(51) Int. Cl. B81B 7/00; B81B 1/00; B81C 1/00

(52) U.S. Cl. CPC B81B 7/007; B81B 1/00; B81B 2201/058; B81C 1/00071; B81C 1/00095

(57) ABSTRACT

A structure includes a molded structure, an integrated circuit (IC) die molded into the molded structure, the IC die including one of a fluidic channel or a sensor, an interposer structure molded into the molded structure, and a via structure embedded within the interposer structure, the via structure fluidically or electrically connecting a top surface of the interposer structure to a bottom surface of the interposer structure.

### BACKGROUND

Microfabrication and micromachining processes can refer to processes in which micrometer scale or smaller structures and devices can be formed. For example, microfluidic systems correspond to various microstructures which can be implemented in microfluidic devices. As another example, microfluidic devices, such as fluid ejection devices, fluid process devices, etc., can correspond to devices of a micrometer or smaller scale that convey, dispense, and/or process small amounts (e.g., microliters, picoliters, etc.) of fluid substances.

### BRIEF DESCRIPTION OF THE DRAWINGS

Non-limiting examples of the present disclosure are described by way of example with reference to the accompanying figures, which are schematic and are not intended to be drawn to scale. Unless indicated as representing the background art, the figures represent aspects of the disclosure. For purposes of clarity, not every component can be labeled in every drawing. In the drawings:

FIG. 1 shows a cross-sectional view of an example microfluidic structure.

FIG. 2A shows a cross-sectional view of an example microfluidic structure.

FIG. 2B shows a top-down view of an example structure.

FIG. 3A to FIG. 3E show cross-sectional views of example microfluidic structures.

FIG. 4A shows a cross-sectional view of a portion of an example structure of FIG. 3C.

FIG. 4B shows a cross-sectional view of a portion of the example structure of FIG. 3E.

FIG. 5 shows a flow chart of an example method.

FIG. 6 shows a flow diagram of an example method.

FIG. 7 shows a flow chart of an example method.

FIG. 8 shows a flow diagram of an example method.

FIG. 9 shows a flow chart of an example method.

FIG. 10 shows a flow diagram of an example method.

### DETAILED DESCRIPTION

In the context of microfluidic structures, such as fluidic integrated circuit (IC) dies, the fluidic IC die may be connected to and/or operate in combination with other fluidic and/or electrical components including, but not limited to, other ICs, microelectromechanical systems (MEMS), printed circuit boards (PCBs), and the like. For example, the microfluidic structure may include fluidic channels, electrical traces, etc., fluidically or electrically connecting different components of the fluidic IC die, such as through fluidic or electrical routing structures. The ability to establish such fluidic and electrical connections, in particular, fluidic fan-out and electrical fan-out, while integrating various components within a limited area remains a challenge. For example, the fluidic IC die can face constraints such as large package size and crowded space for fluidic and electrical routing. These limitations restrict the available physical space for device areas within the package, posing challenges for designing and implementing routing solutions within the device and potentially impacting its performance and functionality. For these reasons and others, there may be a desire for microfluidic structure fabrication methods and structures that enable electrical and fluidic connections in a way that allows for a larger design space, such as compared with current fabrication methods and structures. Although a fluidic or electrical connection structure (referred to as a through-mold via) can be formed by directly processing a molded structure (e.g., drilling an epoxy molded compound (EMC)), such a technique may be limited to a coarse profile and prone to defective features and interference from processing particles (e.g., silica particles).

The present disclosure provides techniques for a microfluidic structure including a fluidic IC die and a connecting structure (hereinafter referred to as “via structure”; e.g., a fluidic via structure, an electrical via structure, etc.) embedded within an interposer structure. As used herein, the term ‘interposer structure’ or ‘interposer’ refer to a predefined structure formed in the microfluidic structure by molding over with mold material (e.g., molding over the predefined structure with the mold material), such as along with the fluidic IC die, while including a temporary structure to be formed for the via structure and/or providing a predefined space for the via structure to be formed therein at downstream.

The techniques as disclosed herein can enable a design that utilizes the via structures embedded within the interposer structures as bridges to establish fluidic and/or electrical connection between various components of the IC die. For example, the via structures embedded within the interposer structure can be formed in a microfluidic structure such that top and bottom surfaces of the microfluidic structure can be fluidically or electrically connected. This approach can enlarge the design space for fluidic and electrical routing, allowing for a decrease in package size and finer-pitch interconnects, thereby enabling a higher degree of heterogeneous integration. Furthermore, the techniques disclosed herein can shorten the signal (e.g., fluidic or electrical) transfer path, which increases fluidic response frequency and faster processing of fluid (e.g., sensing, sorting, mixing, etc.). Incorporating the interposer structure (and the via structure embedded therein) and the IC die within the microfluidic structure can provide benefits such as compared with the current microfluidic structure fabrication methods and structures.

The techniques disclosed herein may offer significant benefits over the through-mold via or a structure formed by directly processing the molded structure (e.g., EMC). The techniques for forming the interposer structures (e.g., silicon) and the embedded via structures can utilize the silicon fabrication technologies, contributing to material flexibility and manufacturing simplicity and providing benefits over the challenges of processing a molded structure like EMC (e.g., challenges such as potential warping, cracking, or deformations of the molded structure due to the susceptibility of EMC to thermal and mechanical stress). Moreover, the surface finish of the via structures formed by etching the interposer structure can be smoother and less defective compared to those formed by drilling EMC. In addition, processing the interposer structures can achieve higher resolution (e.g., finer pitch), allowing for greater design flexibility and increased density of devices. The techniques for forming the interposer structures and the embedded via structures can be performed either prior to molding at the wafer level or post-molding at the package level, adding manufacturing flexibility.

By utilizing the via structures embedded within the interposer structures to establish fluidic and/or electrical connection, the techniques disclosed herein can improve heterogeneous integration of multiple fluidic IC dies with different functionalities, without sacrificing area or manufacturing complexity, while improving the performance of such fluidic packages as fluidic process devices (e.g., for biomaterial, cells, chemical, etc.), fluidic ejection devices (e.g., for printing), etc.

Reference is now made to the figures. Although the figures and aspects of the disclosure can show or describe structures herein as having a particular shape, it should be understood that such shapes are merely illustrative and should not be considered limiting to the scope of the techniques described herein. For example, the techniques described herein can be implemented in any shape or geometry for any material or layer to achieve desired results.

With the foregoing in mind, it should be appreciated, therefore, that techniques for a microfluidic structure (e.g., a microfluidic structure 100) including an IC die (e.g., an IC die 120) and a via structure (e.g., a via structure 140) embedded within an interposer structure (e.g., a interposer structure 130), may be of interest. The present disclosure provides such techniques for the microfluidic structures and forming the same. The figures and description below illustrate various examples of the microfluidic structures and processes of forming the same. It should be noted that the figures and description below are non-limiting examples and can be implemented as any of various other configurations while remaining within the scope of the present disclosure.

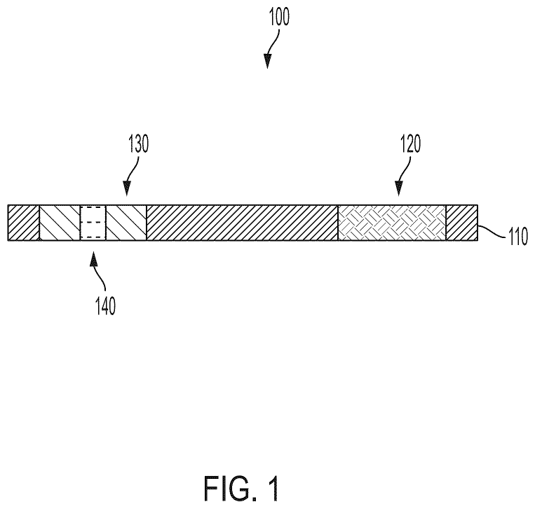

FIG. 1 shows a cross-sectional view of an example microfluidic structure 100. The microfluidic structure 100 can include a molded structure 110, an integrated circuit (IC) dic 120, an interposer structure 130, and a via structure 140. Shown in FIG. 1 is a non-limiting example of the microfluidic structure 100. In some examples, the microfluidic structure 100 can include more, fewer, or different components than shown in or described with respect to FIG. 1.

In some examples, the molded structure 110 can be or include a support for the IC dic 120 and the interposer structure 130. The molded structure 110 can include material for protecting the IC die 120 and the interposer structure 130. For example, the molded structure 110 can be or include an epoxy molding compound (EMC) to encapsulate the IC die 120 and the interposer structure 130. The molded structure 110 can be formed by molding over the IC die 120 and the interposer structure 130.

The IC die 120 can be or include a fluidic device. The fluidic device can be of a fluid ejection device, a fluid process device, etc. to control fluid contained therein. For example, the IC die 120 can be a fluidic ejection die to control fluid (e.g., ejection thereof) in a fluid ejection device, a fluidic process die to process (e.g., sense) fluid in a fluid process device, etc. In some examples, the IC die 120 can include a fluidic channel or a sensor. In some examples, the IC die 120 can include fluidic devices, including but not limited to, a fluidic pump, a valve, a reaction chamber, a sensor, a fluid ejection circuit, a fluid processing circuit, etc. In some examples, the IC die 120 can be molded into the molded structure 110.

The interposer structure 130 can be or include a structure that includes a predefined structure to be formed for the via structure (e.g., the via structure 140) and/or a pre-formed via structure (e.g., the via structure 140), and that is formed in the microfluidic structure 100 by molding over with mold material. In some examples, the interposer structure 130 can be a dummy structure to accommodate the via structure 140. For example, the interposer structure 130 can be a dummy silicon structure, a dummy glass structure, etc., in which the via structure 140 can be formed and/or predefined. In some examples, the interposer structure 130 can be or include a plastic structure, a lead-frame type structure (e.g., stamped, plated, etc.). In some examples, the interposer structure 130 can be or include any compound material that can be processed to form the via structure 140 therein and/or include a predefined portion for the via structure 140. In some examples, the IC die 120 and the interposer structure 130 can be arranged side by side (e.g., arranged in parallel), as shown in FIG. 1. In some examples, the IC die 120 and the interposer structure 130 can be separated from each other by a portion (e.g., the portion disposed therebetween) of the molded structure 110. In some examples, the IC die 120 and/or the interposer structure 130 can form an array in the molded structure 110.

In some examples, the via structure 140 can be a structure embedded within the interposer structure 130. In some examples, the via structure 140 can be embedded within the interposer structure 130 such that the via structure 140 can be separated from the IC die 120 by the interposer structure 130. For example, as shown, the via structure 140 can be embedded within the interposer structure 130, which, along with the molded structure 110, can separate the via structure 140 from the IC die 120. In some examples, the via structure 140 can be or include a fluidic channel, an electrical routing structure, etc. In some examples, the via structure 140 can fluidically or electrically connect a top surface of the interposer structure 130 to a bottom surface of the interposer structure 130. For example, while including such a fluidic channel or an electrical routing structure, the via structure 140 can extend from the bottom surface of the interposer structure 130 to the top surface of the interposer structure 130, as shown in FIG. 1. In some examples, the via structure 140 can be fluidically or electrically connected with the IC die 120. For example, the fluidic channel or the electrical routing structure of the via structure 140 can be fluidically or electrically connected with the IC die 120 through a top and/or a bottom portion of the molded structure 110. When the IC die 120 includes a fluidic channel or sensor, the fluidic channel or the electrical routing structure of the via structure 140 can be fluidically or electrically connected with the fluidic channel or the sensor of the IC die 120.

As discussed above, the via structures (e.g., the via structure 140) embedded within the interposer structures (e.g., the interposer structure 130) can establish fluidic and/or electrical connection between various components of the IC die. For example, as shown in FIG. 1, the via structure 140 embedded within the interposer structure 130 can be formed such that top and bottom surfaces of the microfluidic structure 100 can be fluidically or electrically connected, thereby enlarging the design space for fluidic and electrical routing and increased design flexibility. Furthermore, providing the fluidic and/or electrical connection as discussed herein can shorten the signal (e.g., fluidic or electrical) transfer path and thus enhance the performance of the microfluidic structure 100. In addition, by utilizing the via structures (e.g., the via structure 140) embedded within the interposer structures (e.g., the interposer structure 130), the techniques disclosed herein can improve heterogeneous integration of multiple fluidic IC dies with different functionalities, without sacrificing area or manufacturing complexity.

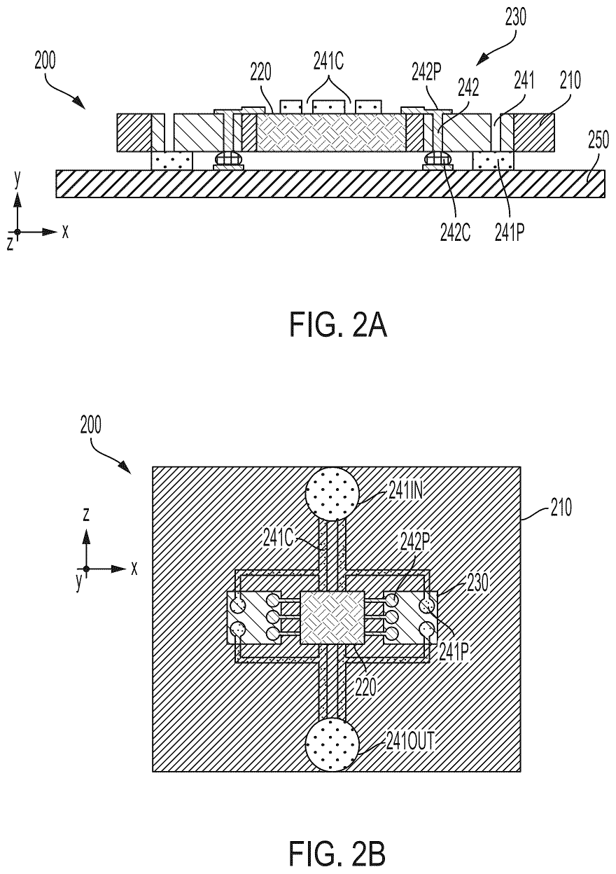

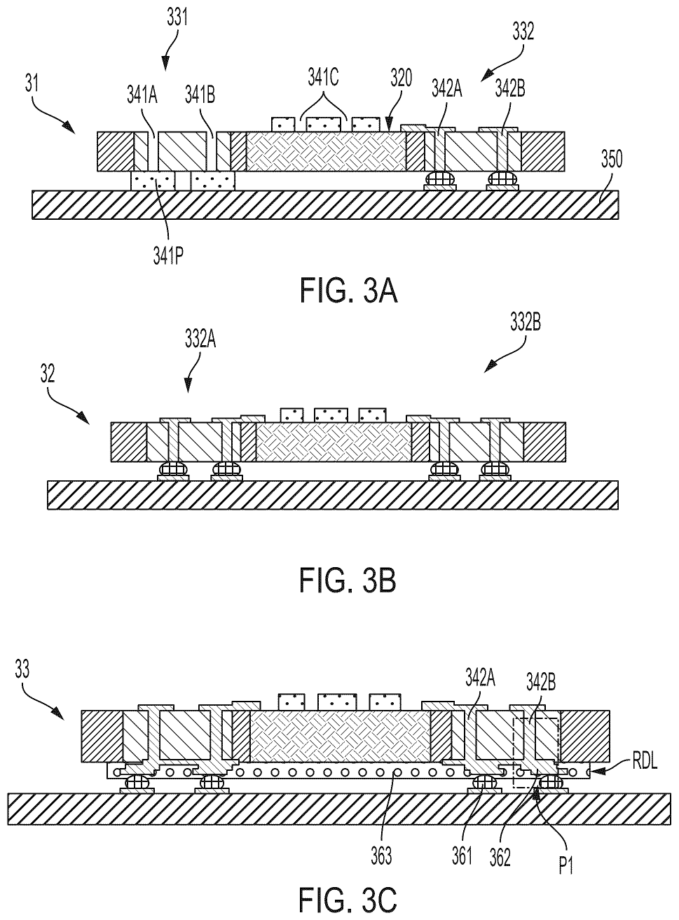

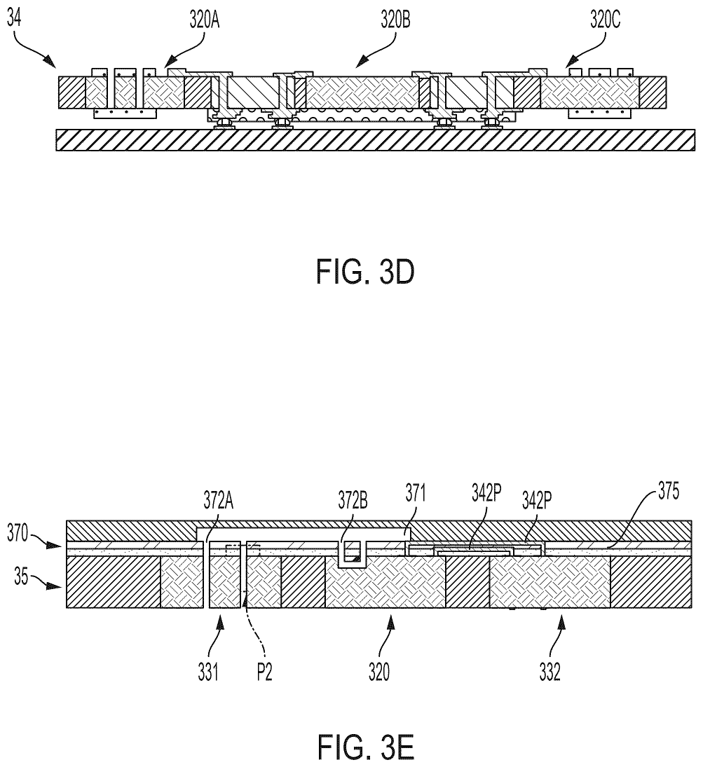

With the foregoing in mind, it should be appreciated, therefore, that techniques for the microfluidic structures (e.g., the microfluidic structure 100), which utilize the via structure (e.g., the via structure 140) embedded within the interposer structure (e.g., the interposer structure 130) in various applications, may be of interest. The figures and description illustrated with respect to FIG. 2A, FIG. 2B, FIG. 3A, FIG. 3B, FIG. 3C, FIG. 3D, FIG. 3E, FIG. 4A, FIG. 4B, etc. provide various examples of the microfluidic structures. It should be noted that the figures and description below are non-limiting examples and can be implemented as any of various other configurations while remaining within the scope of the present disclosure.

FIG. 2A shows a cross-sectional view of an example microfluidic structure 200. FIG. 2B shows a top-down view of the microfluidic structure 200. In some examples, the microfluidic structure 200 can be substantially similar to and/or incorporate features of the microfluidic structures 100. The microfluidic structure 200 can include a molded structure 210, an IC die 220, an interposer structure 230, and a via structure (e.g., a fluidic channel 241, an electrical routing structure 242, etc.), which can be substantially similar to and/or incorporate features of the corresponding structures of the microfluidic structure 200. Shown in FIG. 2A and FIG. 2B is a non-limiting example of the microfluidic structure 200. In some examples, the microfluidic structure 200 can include more, fewer, or different components than shown in or described with respect to FIG. 2A and FIG. 2B.

In some examples, the interposer structure 230 can accommodate a plurality of via structures. For example, as shown, the interposer structure 230 can include the fluidic channel 241 and the electrical routing structure 242. In some examples, the fluidic channel 241 can be or include a fan-out fluidic channel. In some examples, the electrical routing structure 242 can be or include a fan-out electrical routing structure. In some examples, although not shown, the fluidic channel 241 can be or include a fan-in fluidic channel. In some examples, the electrical routing structure 242 can be or include a fan-in electrical routing structure.

In some examples, the via structure (e.g., the fluidic channel 241, the electrical routing structure 242, etc.) can fluidically or electrically connect a top surface of the interposer structure 230 to a bottom surface of the interposer structure 230. For example, as shown, the fluidic channel 241 can fluidically connect a bottom portion of the interposer structure 230 to a top portion of the interposer structure 230. The electrical routing structure 242 can electrically connect a bottom portion of the interposer structure 230 to a top portion of the interposer structure 230.

In some examples, the via structure (e.g., the fluidic channel 241, etc.) can be fluidically connected with the IC die 220. For example, the fluidic channel 241 can be fluidically connected with the IC die 220 through a fluidic port/channel. In some examples, fluid can be input through a fluidic input 241IN and provided to the IC die 220 through a fluidic channel 241C and a fluidic port 241P. The IC die 220 (e.g., a sensor thereof) can process (e.g., sense, detect, etc.) the fluid, which can be output through the fluidic channel 241C and the fluidic port 241P, and then a fluidic output 241OUT. In some examples, the via structure (e.g., the electrical routing structure 242, etc.) can be electrically connected with the IC die 220. For example, the electrical routing structure 242 can be electrically connected with the IC die 220 through a conductive path 242P (e.g., a conductive line, bond pad, wire, etc.). The electrical routing structure 242 can be electrically connected with a printed circuit board (PCB) 250 through a conductive structure 242C. In some examples, the IC die 220 can be controlled through the PCB 250, based on the conductive path from the IC die 220 to the PCB 250 (e.g., the conductive path 242P, the electrical routing structure 242, the conductive structure 242C, etc.). For example, a sensor of the IC die 220 can be electrically controlled to process (e.g., sense, detect, etc.) the fluid based on an electrical signal provided through the conductive path from the IC die 220 to the PCB 250 (e.g., the conductive path 242P, the electrical routing structure 242, the conductive structure 242C, etc.).

In some examples, the microfluidic structure 200 can include a fluidic or electrical connection structure that can fluidically or electrically connect the via structure (e.g., the fluidic channel 241, the electrical routing structure 242, etc.) to the IC die 220 at both sides of the microfluidic structure 200. For example, as shown, the conductive path 242P can electrically connect the IC die 220 with the electrical routing structure 242 at a top surface of the microfluidic structure 200. Although not shown, the microfluidic structure 200 can include a conductive path that can electrically connect the IC die 220 with the electrical routing structure 242 at a bottom surface of the microfluidic structure 200. For example, the microfluidic structure 200 can include a fluidic path that can fluidically connect the IC die 220 with the fluidic channel 241 at a bottom surface and/or a top surface of the microfluidic structure 200.

The fluidic and/or electrical connection at both sides of the microfluidic structure 200 can enlarge the design space for the fluidic and/or electrical routing, while enabling finer-pitch interconnect and higher degree of heterogenous integration. In addition, the shortened fluidic and electrical routing pathways can improve the performance of the fluidic device, while reducing the package size. For example, the signal transfer path and impedance delay can be reduced, and the fluidic response frequency and fluidic process (e.g., sensing, sorting, mixing, etc.) speed can be increased with greater precision.

Shown in FIG. 2A and FIG. 2B is a non-limiting example of the microfluidic structure 200, and any variation of the microfluidic structure 200 can be implemented without departing from the spirit and scope of the present disclosure. In some examples, an interposer structure (e.g., the interposer structure 230) can include a plurality of fluidic channels (e.g., the fluidic channel 241), a plurality of electrical routing structures (e.g., the electrical routing structure 242), or any combination thereof. In some examples, the microfluidic structure 200 can include a plurality of interposer structures (e.g., interposer structure 230), a plurality of IC dies (e.g., the IC die 220), etc., with various arrangement thereof. For example, an interposer structure (e.g., the interposer structure 230) can be disposed between two IC dies (e.g., the IC die 220).

FIG. 3A to FIG. 3E show cross-sectional views of example microfluidic structures 31, 32, 33, 34, 35. The microfluidic structures 31, 32, 33, 34, 35 can be examples of the microfluidic structure 100, the microfluidic structure 200, etc., and can be substantially similar to and/or incorporate features thereof. Shown in FIG. 3A to FIG. 3E are non-limiting examples, and the microfluidic structures 31, 32, 33, 34, 35 can include more, fewer, or different components than shown in or described with respect to FIG. 3A to FIG. 3E.

Referring to FIG. 3A, in some examples, the microfluidic structure 31 can include a first interposer structure 331 and a second interposer structure 332. The first interposer structure 331 can include a first fluidic channel 341A and a second fluidic channel 341B, each of which can be substantially similar to and/or incorporate features of the fluidic channel 241. For example, the first fluidic channel 341A and the second fluidic channel 341B can be fluidically connected with the IC die 320. The fluidic channels 341A, 341B can be fluidically connected with the IC die 320 through a fluidic port/channel. The second interposer structure 332 can include a first electrical routing structure 342A and a second electrical routing structure 342B, each of which can be substantially similar to and/or incorporate features of the electrical routing structure 242. For example, the first electrical routing structure 342A and the second electrical routing structure 342B can be electrically connected with the IC die 320 through a conductive path (e.g., a conductive line, bond pad, wire, etc.). The electrical routing structures 342A, 342B can be electrically connected with a PCB 350 through a conductive structure.

In some examples, each of the first interposer structure 331 (e.g., the via structures therein such as fluidic channels and/or electrical routing structures, etc.) and the second interposer structure 332 (e.g., the via structures therein such as fluidic channels and/or electrical routing structures, etc.) can serve a certain functionality. In some examples, the first interposer structure 331 (e.g., the via structures therein such as fluidic channels and/or electrical routing structures, etc.) can be to serve as a “fluidic” interposer that facilitates fluidic control in the microfluidic structure 31. For example, the first interposer structure 331 can include the fluidic channels 341A, 341B and additionally include other fluidic components. In some examples, the second interposer structure 332 (e.g., the via structures therein such as fluidic channels and/or electrical routing structures, etc.) can be to serve as an “electrical” interposer that facilitates electrical control in the microfluidic structure 31 (e.g., the IC die 320). For example, the second interposer structure 332 can include the electrical routing structures 342A, 342B and additionally include other electrical components. In some examples, the IC die 320 can be controlled by an electrical signal provided through the second interposer structure 332, such that fluid provided through the first interposer structure 331 (and/or a fluidic port 341P, a fluidic channel 341C, etc.) can be processed by the IC die 320. As discussed herein, the interposer structures (and the via structures embedded therein) of the present disclosure can offer flexible pathways for fluidic and/or electrical routing, allowing for operation of multiple active components (e.g., fluidic devices, sensors, etc.) with a high density.

Referring to FIG. 3B, in some examples, the microfluidic structure 32 can include the second interposer structures 332 (referred to as the interposer structure 332A and the interposer structure 332B herein with respect to FIG. 3B) at both sides of the IC die 320. In some examples, each of the interposer structure 332A (e.g., the via structures therein such as electrical routing structures, etc.) and the interposer structure 332B (e.g., the via structures therein such as electrical routing structures, etc.) can serve a certain electrical functionality. In some examples, the interposer structure 332A (e.g., the via structures therein such as electrical routing structures, etc.) can serve a first electrical function associated with the IC die 320, and the interposer structure 332B (e.g., the via structures therein such as electrical routing structures, etc.) can serve a second electrical function associated with the IC die 320. For example, the electrical routing structures of the interposer structure 332A can be used to control fluidic devices (e.g., a valve, a pump, etc.) associated with the IC die 320. The electrical routing structures of the interposer structure 332B can be used to control other aspects of the IC die 320 (e.g., a sensor, etc.). In some examples, the IC die 320 can be controlled by an electrical signal provided through the interposer structures 332A, 332B, such that fluid provided to the IC die 320 (e.g., through the fluidic channel 341C, etc.) can be processed by the IC die 320.

Referring to FIG. 3C, in some examples, the microfluidic structure 33 can be electrically connected to the PCB 350. For example, the electrical routing structures 342A, 342B of the microfluidic structure 33 can be electrically connected to the PCB 350. In some examples, the electrical routing structures 342A, 342B of the microfluidic structure 33 can be electrically connected to the PCB 350 through various conductive structures. As shown, for example, the electrical routing structures 342A, 342B of the microfluidic structure 33 can be electrically connected to the PCB 350 through various conductive structures/paths, such as solder balls 361, redistribution layers (RDLs) 362, copper pillars, etc. In some examples, a passivation layer 363 can be disposed where the RDLs 362 are connected to the electrical routing structures 342A, 342B of the microfluidic structure 33. The electrical connection between the microfluidic structure 33 and the PCB 350 are discussed in greater detail with respect to FIG. 4B.

Referring to FIG. 3D, in some examples, the microfluidic structure 34 can be integrated with multiple IC dies (e.g., IC dies 320A, 320B, 320C). Each of the IC dies 320A, 320B, and 320C can perform different operations for a higher-level assembly with different functionalities and characteristics. For example, the IC die 320A can be a fluidic device, including but not limited to, thermal inkjet components, piezoelectric inkjet components, sensors, optical components, etc. The IC die 320C can be a fluidic device, including but not limited to, thermal inkjet components, piezoelectric inkjet components, sensors, optical components, etc. The IC die 320A and the IC die 320C can perform a different operation or a same operation. In some examples, the IC die 320B can be or include a logic device (e.g., an application-specific IC (ASIC)), a memory device, etc. By heterogeneously integrating the IC dies 320A, 320B, 320C with different functionalities and/or characteristics, including the logic device, onto a single molded structure, the microfluidic structure 34 can perform various operations. For example, the IC die 320B, including the logic device, can perform fluidic control and/or sensing using the IC die 320A and the IC die 320C, through the electrical routing structures connected thereto. This can improve the design flexibility, while enabling incorporation of multiple devices with different functionalities.

Referring to FIG. 3E, in some examples, the microfluidic structure 35 can be integrated with a fluidic structure 370. In some examples, the fluidic structure 370 can be vertically stacked on the microfluidic structure 35. The fluidic structure 370 can include various fluidic components, including but not limited to, a fluidic chamber 371, a fluidic opening, a reservoir, fluidic channels 372A, 372B, etc. For example, the fluidic structure 370 can include a structure in which fluid is stored and/or a channel in which the fluid can flow. In some examples, as shown, the fluidic structure 370 can be fluidically or electrically connected with the microfluidic structure 35. For example, as shown, the fluidic structure 370 can be fluidically connected with the interposer structure 331 (e.g., the fluidic channels thereof). The fluidic structure 370 can be electrically connected with the interposer structure 332 (e.g., the electrical routing structure thereof). The fluidic structure 370 can be fluidically connected with the IC die 320 (e.g., the fluidic channels thereof) such that the IC die 320 can process fluid provided by the fluidic structure 370. For example, the IC die of FIG. 3E can include a sensor to process (e.g., sense, detect, etc.) the fluid provided through the fluidic channel 372B from the fluidic chamber 371. The processing of the fluid can be controlled by electrical signals, which can be provided through the interposer structure 332, as shown in FIG. 3E.

In some examples, the fluidic structure 370 can include a passivation layer 375. In some examples, the passivation layer 375 can include a plurality of passivation layers. The passivation layer 375 can provide passivation of conductive paths 342P, such that the electrical routing can be passivated from each other and/or from other components (e.g., fluidic channel, etc.). In some examples, the passivation layer 375 can include fluidic channels (e.g., the fluidic channels 372A, 372B) or part thereof, which can fluidically connect the microfluidic structure 35 with the fluidic components (e.g., the fluidic chamber 371) of the fluidic structure 370. In some examples, the fluidic structure 370 can include an adhesion layer. For example, the adhesion layer can be disposed between the microfluidic structure 35 and the passivation layer 375.

In some examples, the fluidic structure 370 (e.g., the passivation layer 375) can be or include photo-patternable material, chemically/mechanically resistant material, etc. For example, the fluidic structure 370 (e.g., the passivation layer 375) can be or include SU8, polyimide (PI), polybenzoxazole (PBO), Benzocyclobutene (BCB), etc. Although not shown, in some examples, the fluidic structure 370 can be integrated with the microfluidic structure 35 at the bottom side of the microfluidic structure 35, or at both sides thereof.

FIG. 4A shows a cross-sectional view of a portion P1 of the example microfluidic structure 35 of FIG. 3C. Shown in FIG. 4A is a non-limiting example, and the portion P1 can include more, fewer, or different components than shown in or described with respect to FIG. 4A. In some examples, a coating layer 441, a barrier layer 442, etc. can be omitted (e.g., as omitted in FIG. 3C).

In some examples, the electrical routing structure 342B can be electrically connected to other components (e.g., the PCB 350) through a conductive path (e.g., the solder balls 361, the RDLs 362, copper pillars, etc.). As shown, the passivation layer 363 can include the RDLs 362. The RDLs 362 can electrically connect the electrical routing structure 342B and the solder balls 361 (e.g., which can be electrically connected to the PCB 350, as shown in FIG. 3C). The RDLs 362, for example, can include a conductive trace electrically connecting the PCB 350 and the electrical routing structure 342B, while including a passivation film (e.g., dielectric structures). In some examples, as shown, the conductive path (e.g., the RDLs 362, the solder balls 361, copper pillars, microbump structures, etc.) can be electrically connected through an under bump metallization (UBM) structure.

In some examples, the portion P1 (and/or other portions of the microfluidic structure) can include the coating layer 441. The coating layer 441 can be or include, but not limited to, silicon dioxide, silicon nitride, etc., for example. The coating layer 441 can be a layer to protect the material (e.g., silicon) of the interposer structure 332. In some examples, the portion P1 can include the barrier layer 442. The barrier layer 442 can be or include, but not limited to, titanium/copper, tantalum/copper, etc. The barrier layer 442 can be a barrier and seed layer to serve as a diffusion barrier. The barrier layer 442 can surround the electrical routing structure 342B and/or can be disposed between the electrical routing structure 342B and the interposer structure 332 to prevent the diffusion from the electrical routing structure 342B into the interposer structure 332.

FIG. 4B shows a cross-sectional view of a portion P2 of the example microfluidic structure 35 of FIG. 3E. Shown in FIG. 4B is a non-limiting example, and the portion P2 can include more, fewer, or different components than shown in or described with respect to FIG. 4B. In some examples, a coating layer 443, etc. can be omitted (e.g., as omitted in FIG. 3E).

In some examples, the portion P2 (and/or other portions of the microfluidic structure) can include the coating layer 443. The coating layer 443 can be or include, but not limited to, silicon dioxide, silicon nitride, dielectric material (e.g., aluminum oxide, silicon carbide, hafnium oxide, etc.), metal (titanium, tantalum, etc.), etc., for example. The coating layer 443 can be a layer to protect the material (e.g., silicon) of the interposer structure 331. In some examples, the coating layer 443 can prevent the material of the interposer structure 331 from being exposed to fluid flowing through the fluidic channel 341B. This can thereby protect the interposer structure 331 from corrosion or a reaction with the fluid.

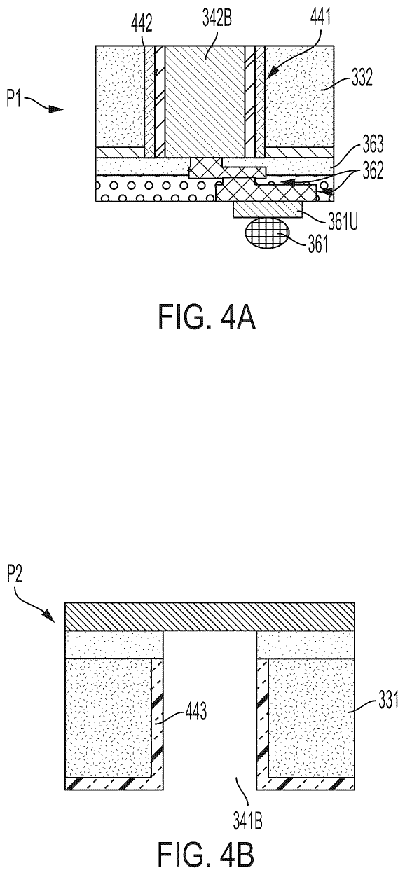

In the description below with respect to FIG. 5 to FIG. 10, example methods of forming the microfluidic structure (e.g., the microfluidic structure 100) including the IC die (e.g., the IC die 120) and the via structure (e.g., the via structure 140) embedded within the interposer structure (e.g., the interposer structure 130), are discussed. It should be noted that the figures and description below are non-limiting examples and can be implemented as any of various other configurations while remaining within the scope of the present disclosure.

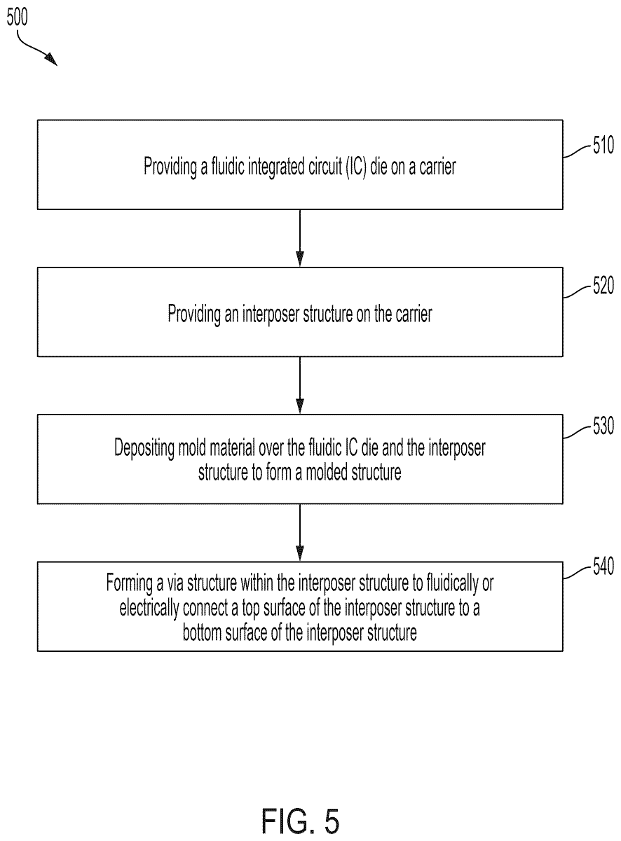

FIG. 5 shows a flow chart of an example method 500. FIG. 6 shows a flow diagram of an example process (e.g., the method 500). The method 500 can be associated with an example structure at various fabrication stages shown in FIG. 6. It is noted that the method 500 and the flow diagram of FIG. 6 are non-limiting examples. Accordingly, it should be understood that additional operations and/or flows can be provided before, during, or after any of the method 500 of FIG. 5, and/or any of the flow diagram of FIG. 6, that any of the method 500 of FIG. 5, and/or any of the flow diagram of FIG. 6 can be omitted, and that some other operations or flow diagrams can be briefly described herein.

In a brief overview, the method 500 can start with operation 510 of providing a fluidic IC die on a carrier. The method 500 can continue to operation 520 of providing an interposer structure on the carrier. The method 500 can continue to operation 530 of depositing mold material over the fluidic IC die and the interposer structure to form a molded structure. The method 500 can continue to operation 540 of forming a via structure within the interposer structure to fluidically or electrically connect a top surface of the interposer structure to a bottom surface of the interposer structure.

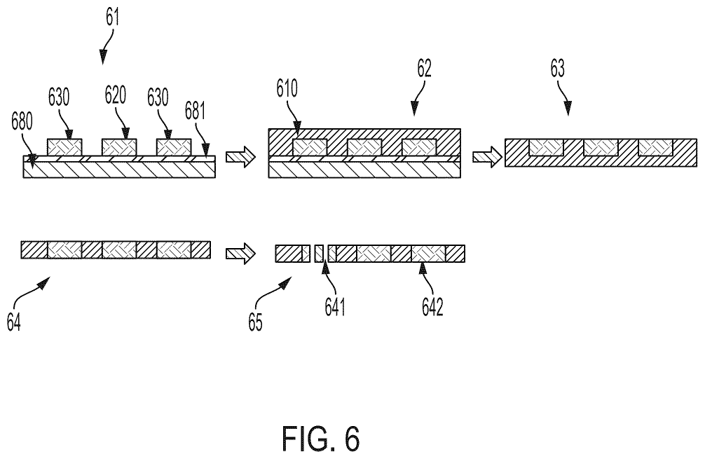

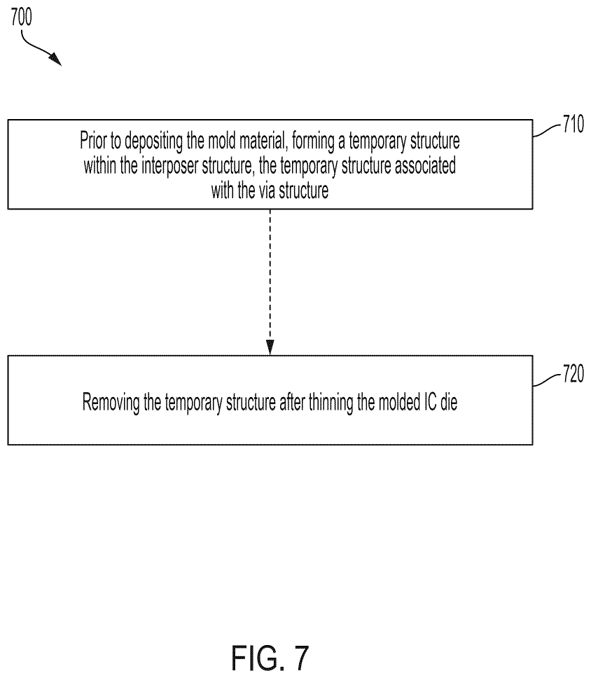

At operation 510 and operation 520 of FIG. 5, a structure 61 of FIG. 6 is formed, in which an IC die 620 and an interposer structure 630 are provided on a carrier 680. In some examples, the IC die 620 and the interposer structure 630 can be provided on the carrier 680 by pick and placement. In some examples, the IC die 620 can include one of a fluidic channel or a sensor. In some examples, the interposer structure 630 can be a dummy structure (e.g., silicon, glass, etc.) that can be processed at a downstream process as discussed with respect to operation 540. In some examples, the interposer structure 630 can include a temporary structure as discussed with respect to FIG. 7 and FIG. 8. In some examples, as shown, a plurality of IC dies 620 and/or a plurality of interposer structure 630 can be provided on the carrier 680. In some examples, the carrier 680 can be a substrate, a wafer, a panel, a frame, or any platform onto which the IC die 620 and the interposer structure 630 can be attached (e.g., by pick and placement). For example, the carrier 680 can be or include a wafer level packaging (e.g., 8-inch wafers, 12-inch wafers, etc.), a panel level packaging (e.g., 300 mm by 100 mm panels, 500 mm by 50 mm panels, etc.), etc. In some examples, the carrier 680 can include a temporary film 681 onto which the IC die 620 and the interposer structure 630 can be attached. The temporary film 681 can be or include a double-side tape, a thermal release film, a ultra-violet film, a light to heat conversion adhesive (LTHC), etc.

At operation 530 of FIG. 5, a structure 62 of FIG. 6 is formed, in which mold material is deposited over the IC die 620 and the interposer structure 630 to form a molded structure 610. The molded structure 610 can be formed by molding over or encapsulating the IC die 620 and the interposer structure 630. In some examples, at operation 530, various molding techniques can be utilized to mold over the IC die 620 and the interposer structure 630. For example, transfer molding, compression molding, etc. can be performed to form the molded structure 610. After forming the molded structure 610 at operation 530, a structure 63 of FIG. 6 can be removed from the carrier 680. In some examples, the structure 63 of FIG. 6 can be released from the temporary film 681 of the carrier 680. The structure 63 can be referred to as a “molded IC die.” In some examples, at operation 520 of FIG. 5, a structure 64 of FIG. 6 is formed, in which the molded IC die is thinned (e.g., thinned from the structure 63 to the structure 64). In some examples, at operation 530, various thinning process can be performed, including but not limited to, grinding, poly-grinding, chemical mechanical polishing (CMP), etc. In some examples, the molded IC die can be thinned until the IC die 620 and the interposer structure 630 can be exposed at a top surface and a bottom surface of the structure 64. In some examples, at operation 530, to form the molded IC die, a surface manipulation can be performed. For example, a dry etch, a wet etch, laser etching, polishing, etc. can be performed on the molded IC die after and/or before the thinning of the molded IC die. In some examples, at operation 530, the molded IC die can be flattened or planarized.

At operation 540 of FIG. 5, a structure 65 of FIG. 6 is formed, in which a via structure (e.g., a fluidic channel 641, an electrical routing structure 642, etc.) can be formed in the interposer structure 630. For example, the fluidic channel 641 can be a fan-out fluidic channel structure. The electrical routing structure 642 can a fan-out electrical routing structure. In some examples, any of fluidic devices, such as a fluidic pump, a valve, a reaction chamber, a sensor, a fluid ejection circuit, a fluid processing circuit, MEMS, etc., can be formed in the interposer structure 630 and/or the IC die 620. In some examples, various techniques can be used to form the fluidic device. For example, a fabrication process to form the fluidic device can be performed, including but not limited to, etching, lithography, depositing, etc.

As discussed herein, the interposer structure (e.g., the interposer structure 630) can provide a predefined space in the molded structure (e.g., the molded structure 610), which can be further processed to form the via structures (e.g., the fluidic channel 641 and/or the electrical routing structure 642), while molding over the interposer structure and the IC die (e.g., the IC die 620) in a single package connects the embedded via structures with the IC die. In particular, placing the interposer structure prior to molding over (e.g., at operation 520) allows for the predefined structure, in which a temporary structure can be formed for the via structure and/or a predefined space can be provided for the via structure to be formed therein at downstream. This can thereby enable formation of the via structures (e.g., the fluidic channel 641 and/or the electrical routing structure 642) without directly processing the molded structure (e.g., molded structure 610) to form the via structures.

As the fluidic channel 641 and/or the electrical routing structure 642 can be formed by processing the interposer structure 630 (e.g., through semiconductor fabrication technologies), without directly processing the molded structure 610, the structure 65 can be used for microfluidic devices with such benefits as material flexibility, manufacturing simplicity, etc. and those over the challenges of processing the EMC molded structure.

FIG. 7 shows a flow chart of an example method 700. FIG. 8 shows a flow diagram of an example process (e.g., the method 700). The method 700 can be associated with an example structure at various fabrication stages shown in FIG. 8. It is noted that the method 700 and the flow diagram of FIG. 8 are non-limiting examples. Accordingly, it should be understood that additional operations and/or flows can be provided before, during, or after any of the method 700 of FIG. 7, and/or any of the flow diagram of FIG. 8, that any of the method 700 of FIG. 7, and/or any of the flow diagram of FIG. 8 can be omitted, and that some other operations or flow diagrams can be briefly described herein.

Referring to FIG. 7, operation 710 and operation 720 can be performed along with the method 500 of FIG. 5. In some examples, operation 710 can be performed prior to operation 530. At operation 710, a structure 81 of FIG. 7 is formed, in which a temporary structure 810 is formed within the interposer structure 630, prior to depositing the mold material to form the molded structure 610. In some examples, the temporary structure 810 can be formed within the interposer structure 630, after the interposer structure 630 is provided onto the carrier 680. In some examples, the temporary structure 810 can be formed within the interposer structure 630, before the interposer structure 630 is provided onto the carrier 680. That is, the interposer structure 630 including the temporary structure 810 can be provided onto the carrier 680 (e.g., prior to operation 510). In some examples, the temporary structure 810 can be associated with the via structure (e.g., a fluidic channel 841, an electrical routing structure 842, etc.) to be formed in the interposer structure 630.

In some examples, at operation 710, a via structure 811 (e.g., the electrical routing structure 642) can be formed within the interposer structure 630, prior to depositing the mold material to form the molded structure 610. In some examples, the via structure 811 can be formed within the interposer structure 630, after the interposer structure 630 is provided onto the carrier 680. In some examples, the via structure 811 can be formed within the interposer structure 630, before the interposer structure 630 is provided onto the carrier 680. That is, the interposer structure 630 including the via structure 811 can be provided onto the carrier 680 (e.g., prior to operation 510).

Referring to FIG. 8, structures 82, 83, 84 can be formed similar to the corresponding structures discussed with respect to FIG. 5 and FIG. 6. In some examples, operation 720 can be performed after operation 530. At operation 720, the structure 85 of FIG. 8 is formed, in which the temporary structure 810 is removed, after thinning the molded IC die (e.g., the structure 84). In some examples, the temporary structure 810 can be removed by selectively etching the temporary structure 810. For example, at operation 720, a wet etching can be performed to selectively strip the temporary structure 810 without affecting the other components (e.g., the IC die 620, the via structure 811, etc.). In some examples, after removing the temporary structure 810, a via structure (e.g., the fluidic channel 841, an electrical routing structure, etc.) can be formed in a space left by the temporary structure 810. In some examples, an additional process (e.g., etching, lithography, depositing, etc.) can be performed to form the via structure. As discussed herein, the temporary structure 810 can predefine the via structure (e.g., the fluidic channel, the electrical routing structure, etc.).

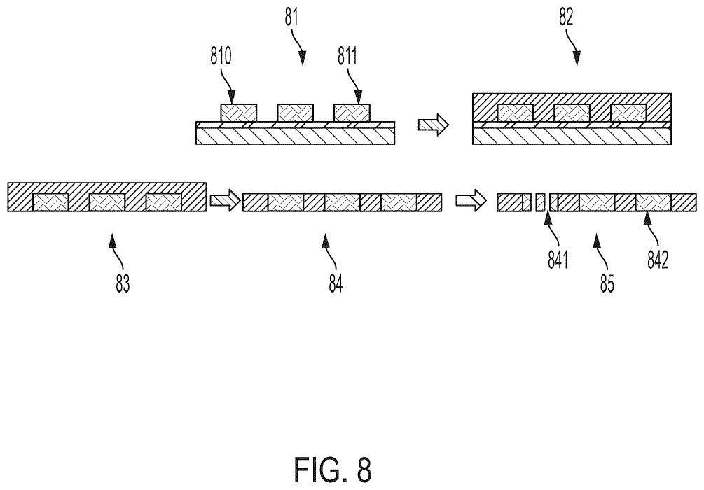

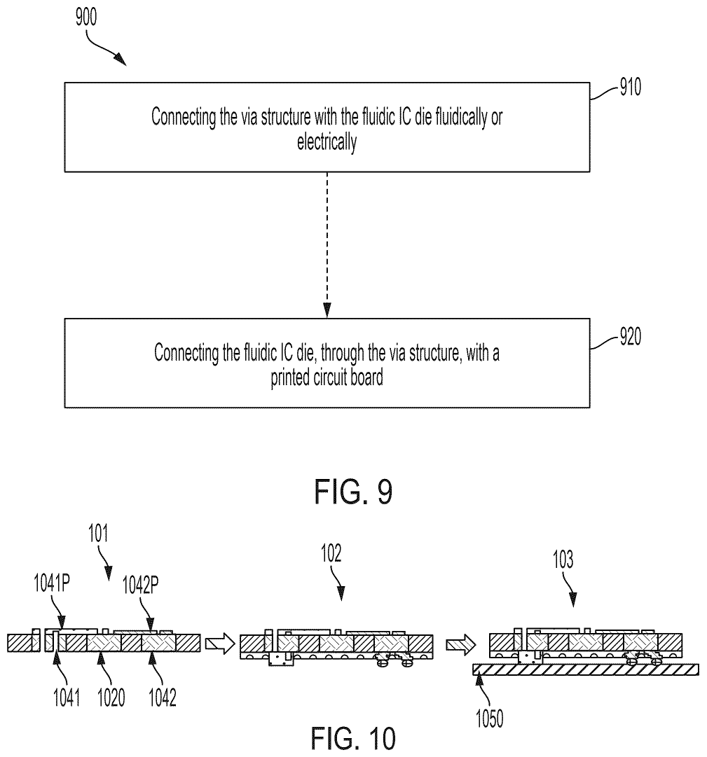

FIG. 9 shows a flow chart of an example method 900. FIG. 10 shows a flow diagram of an example process (e.g., the method 900). Referring to FIG. 9, operation 910 and operation 920 can be performed along with the method 500 of FIG. 5 and/or the method 700 of FIG. 7. In some examples, operation 910 can be performed after forming the via structure. In some examples, operation 910 can be performed on the structure 65 or the structure 85.

At operation 910, a structure 101 of FIG. 10 is formed, in which the via structure (e.g., a fluidic channel 1041, an electrical routing structure 1042, etc.) is connected with an IC die 1020 fluidically or electrically. As shown, a fluidic channel structure 1041P can fluidically connect the IC die 1020 with the fluidic channel 1041. A conductive path 1042P can electrically connect the IC die 1020 with the electrical routing structure 1042. In some examples, at operation 910, a structure 102 of FIG. 10 can be formed, in which various connecting structures (e.g., fluidic channels, RDLs, solder balls, etc.) can be formed. At operation 920, a structure 103 of FIG. 10 is formed, in which the IC die 1020 and/or the structure 102 can be connected with a printed circuit board 1050, through the via structure (e.g., the fluidic channel 1041, the electrical routing structure 1042, etc.).

It should be understood that examples described herein should be considered in a descriptive sense and not for purposes of limitation. Descriptions of features or aspects within each example should be considered as available for other similar features or aspects in other examples. While examples have been described with reference to the figures, it should be understood that various changes in form and details can be made therein without departing from the spirit and scope as defined by the following claims.

The preceding description has been presented to illustrate and describe examples of the principles described. This description is not intended to be exhaustive or to limit these principles to any precise form disclosed. Many modifications and variations are possible in light of the description. Therefore, the foregoing examples provided in the figures and described herein should not be construed as limiting of the scope of the disclosure, which is defined in the Claims.

The disclosure has been described above with reference to the various examples. However, it is to be understood by those of ordinary skill in the art that various modifications can be made in form and detail without departing from the scope of the disclosure as defined by the appended claims and their equivalents.

Conditional language used herein, such as, among others, “can,” “could,” “might,” “may,” “e.g.,” and the like, unless specifically stated otherwise, or otherwise understood within the context as used, is generally intended to convey that certain examples include, while other examples do not include, certain features, elements, etc. Thus, such conditional language is not generally intended to imply that an example include logic for deciding, with or without other input or prompting, whether these features, elements, etc. are included or are to be performed in any particular example. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

While the above detailed description has shown, described, and pointed out novel features as applied to various examples, it can be understood that various omissions, substitutions, and changes in the form and details of the structures or processes illustrated can be made without departing from the spirit of the disclosure. As can be recognized, certain examples described herein can be embodied within a form that does not provide all of the features and benefits set forth herein, as some features can be used or practiced separately from others.

The herein described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components.

With respect to the use of substantially any plural and/or singular terms herein, those having skill in the art can translate from the plural to the singular and/or from the singular to the plural as is appropriate to the context and/or application. The various singular/plural permutations can be expressly set forth herein for sake of clarity.

It should be understood by those within the art that, in general, terms used herein, and especially in the appended claims (e.g., bodies of the appended claims) are generally intended as “open” terms (e.g., the term “including” should be interpreted as “including but not limited to,” the term “includes” should be interpreted as “includes but is not limited to,” etc.). It should be understood by those within the art that if a specific number of an introduced claim recitation is intended, such an intent should be explicitly recited in the claim, and in the absence of such recitation no such intent is present. In those instances where a convention analogous to “one of A, B, and C, etc.” is used, in general such a construction is intended in the sense one having skill in the art would understand the convention (e.g., “a system having one of A, B, and C” would include but not be limited to systems that have A alone, B alone, C alone, A and B together, A and C together, B and C together, and/or A, B, and C together, etc.). In those instances, where a convention analogous to “one of A, B, or C, etc.” is used, in general such a construction is intended in the sense one having skill in the art would understand the convention (e.g., “a system having one of A, B, or C” would include but not be limited to systems that have A alone, B alone, C alone, A and B together, A and C together, B and C together, and/or A, B, and C together, etc.). It should be understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.” Unless otherwise noted, the use of the words “approximate,” “about,” “around,” “substantially,” etc., mean plus or minus ten percent.

What is claimed:

1. A structure, comprising:
a molded structure;
an integrated circuit (IC) die molded into the molded structure, the IC die including one of a fluidic channel or a sensor;
an interposer structure molded into the molded structure; and
a via structure embedded within the interposer structure, the via structure fluidically or electrically connecting a top surface of the interposer structure to a bottom surface of the interposer structure.

2. The structure of claim 1, wherein the one of the fluidic channel or the sensor is fluidically or electrically connected with the via structure.

3. The structure of claim 1, wherein the via structure includes a fan-out fluidic channel or a fan-out electrical routing structure.

4. The structure of claim 1, wherein the IC die and the interposer structure are arranged side by side, while separated from each other by a portion of the molded structure.

5. The structure of claim 1, wherein the via structure includes one of a coating layer to prevent the interposer structure from being exposed to fluid or a barrier layer to serve as a diffusion barrier.

6. The structure of claim 1, wherein the via structure is electrically connected to a printed circuit board.

7. A structure, comprising:
a molded structure;
a fluidic integrated circuit (IC) die molded into the molded structure;
an interposer structure molded into the molded structure and arranged parallel to the fluidic IC die; and
a via structure separated from the fluidic IC die by the interposer structure, the via structure including one of a fluidic channel or an electrical routing structure.

8. The structure of claim 7, wherein the fluidic IC die is fluidically or electrically connected with the via structure.

9. The structure of claim 7, wherein the IC die and the interposer structure are separated from each other by a portion of the molded structure.

10. The structure of claim 7, comprising a fluidic structure in which fluid flows or is stored, the fluidic structure vertically stacked on the structure and fluidically connected with the via structure and the fluidic IC die.

11. The structure of claim 10, wherein the fluidic IC die includes a sensor to process the fluid.

12. The structure of claim 7, wherein the via structure is electrically connected to a printed circuit board.

13. The structure of claim 7, comprising a layer disposed between the via structure and the interposer structure, the layer including a coating layer or a diffusion barrier.

14. A method, comprising:
providing a fluidic integrated circuit (IC) die on a carrier;
providing an interposer structure on the carrier;
depositing mold material over the fluidic IC die and the interposer structure to form a molded structure;
removing the carrier; and
forming a via structure within the interposer structure to fluidically or electrically connect a top surface of the interposer structure to a bottom surface of the interposer structure.

15. The method of claim 14, comprising:
prior to depositing the mold material, forming a temporary structure within the interposer structure, the temporary structure associated with the via structure.

16. The method of claim 14, wherein the fluidic IC die includes one of a fluidic channel or a sensor.

17. The method of claim 14, wherein the via structure includes a fan-out fluidic channel or a fan-out electrical routing structure.

18. The method of claim 14, comprising:
connecting the via structure with the fluidic IC die fluidically or electrically.

19. The method of claim 18, comprising:
connecting the fluidic IC die, through the via structure, with a printed circuit board.

20. The method of claim 14, comprising:
prior to forming the via structure, thinning a portion of the molded structure such that the interposer structure is exposed at a top surface and a bottom surface.
